(19) United States
(12) Patent Application Publication
(10) Pub. No.: US 2011/0203513 A1
(43) Pub. Date: Aug. 25, 2011

(54) METHOD OF MANUFACTURING SILICON CARBIDE SUBSTRATE

(75) Inventors: Hiroki WATANABE, Tokai-city (JP); Yasuo Kitou, Okazaki-city (JP); Kensaku Yamamoto, Chiryu-city (JP); Hidefumi Takaya, Miyoshi-city (JP); Masahiro Sugimoto, Toyota-city (JP); Jun Morimoto, Nisshin-city (JP); Yukihiko Watanabe, Nagoya-city (JP); Narumasa Soejima, Seto-city (JP); Tsuyoshi Ishikawa, Nisshin-city (JP)

(73) Assignees: DENSO CORPORATION, Kariya-city (JP); TOYOTA JIDOSHA KABUSHIKI KAISHA, Toyota-city (JP)

(21) Appl. No.: 13/029,791

(22) Filed: Feb. 17, 2011

(30) Foreign Application Priority Data
Feb. 19, 2010 (JP) 2010-34669

(51) Int. Cl. C30B 19/12

(52) U.S. Cl. 117/54

(57) ABSTRACT

In a method of manufacturing a silicon carbide substrate, a defect-containing substrate made of silicon carbide is prepared. The defect-containing substrate has a front surface, a rear surface being opposite to the front surface, and a surface portion adjacent to the front surface. The detect-containing substrate includes a screw dislocation in the surface portion. The front surface of the defect-containing substrate is applied with an external force so that a crystallinity of the surface portion is reduced. After being applied with the external force, the defect-containing substrate is thermally treated so that the crystallinity of the surface portion is recovered.

### CROSS REFERENCE TO RELATED APPLICATIONS

The present application is based on and claims priority to Japanese Patent Application No. 2010-34669 filed on Feb. 19, 2010, the contents of which are incorporated in their entirety herein by reference.

### BACKGROUND OF THE INVENTION

1. Field of the Invention

The present invention relates to a method of manufacturing a silicon carbide (SiC) substrate.

2. Description of the Related Art

Conventionally, a SiC substrate can be used for a high-voltage device. However, a crystal defect in the SiC substrate may affect a device property. Especially, a screw dislocation in the crystal defect may cause a large distortion. Thus, when a device such as a PN diode and a MOSFET is manufactured with a SiC substrate including a screw distortion in a surface portion thereof, the screw distortion may cause a leak current as described, for example, in “Study and Analysis of Reverse Characteristic of Al-ion Doped C-plane PN Diode” by Takashi Tsuji in the Proceedings of the 4th Individual Discussion of the SiC and Related Wide Bandgap Semiconductors of the Japan Society of Applied Physics, Jul. 31, 2009, page 74 and “Relationship among Forming Method, Channel Mobility, and Reliability of C-plane 4H—SiC MOS Gate Insulating Film” by Takuma Suzuki in the Proceedings of the 4th Individual Discussion of the SiC and Related Wide Bandgap Semiconductors of the Japan Society of Applied Physics, Jul. 31, 2009, page 50.

JP-A-2003-119097 (corresponding to US 2003/0070611 A1) discloses a method of manufacturing a SiC substrate that reduces screw dislocations in a surface portion. In the method, a first seed crystal made of a SiC single crystal is prepared. Then, a SiC single crystal is grown in a <1-100> direction on a main surface of a (1-100) plane of the first seed crystal. Then, the grown SiC single crystal is sliced so as to form a second seed crystal having a main surface of a (11-20) plane. After a SiC single crystal is grown in a <11-20> direction of the second seed crystal, the grown SiC single crystal is sliced so as to form a third seed crystal having a main surface of a (0001) plane. A SiC single crystal is grown in a <0001> direction of the third seed crystal so as to form a SiC single crystal ingot. A SiC substrate can be formed by slicing the SiC single crystal ingot.

In such a manufacturing method, a screw dislocation is liable to be generated when a SiC single crystal is grown in the <0001> direction, and a stacking fault is generated more easily than a screw dislocation when a SiC single crystal is grown in the <1-100> direction or the <11-20> direction. Thus, when a SiC single crystal is grown in the <1-100> direction or the <11-20> direction, generation of a screw dislocation in the SiC single crystal can be restricted. Thus, a screw dislocation is restricted on a main surface of the third seed crystal. When a SiC single crystal is grown, the SiC single crystal inherits a defect (distortion) that exists on a main surface of a seed crystal.

Because a screw dislocation is restricted on the main surface of the third seed crystal, when a SiC single crystal is grown on the third seed crystal so as to form a SiC single crystal ingot, generation of a screw dislocation in the SiC single crystal ingot can be restricted. Thus, when the SiC single crystal ingot is sliced so as to form a SiC substrate, a screw dislocation included in the SiC substrate can be reduced, and a screw dislocation in a surface portion of the SiC substrate can be restricted.

However, in the above-described method, an end of a stacking fault generated when the SiC single crystal is grown in the <1-100> direction or the <11-20> direction may reach the main surface of the third seed crystal. In the above-described case, when a SiC single crystal is grown on the main surface of the third seed crystal so as to form a SiC single crystal ingot, although a screw dislocation is restricted on the main surface of the third seed crystal, a screw dislocation may be generated from the end of the stacking fault by inheriting distortion in the <0004> direction. When a screw dislocation is generated in the SiC single crystal ingot and the SiC single crystal ingot is sliced so as to form a SiC substrate, a screw dislocation may be included in the SiC substrate, and a screw dislocation may be included in a surface portion of the SiC substrate.

In addition, in the above-described method, a growth direction needs to be changed while the SiC single crystal is grown. Thus, a manufacturing process is complex.

### SUMMARY OF THE INVENTION

In view of the foregoing problems, it is an object of the present invention to provide a method of manufacturing a SiC substrate that can restrict a screw distortion in a surface portion of the SiC substrate.

In a method of manufacturing a SiC substrate according to an aspect of the present invention, a defect-containing substrate made of SiC is prepared. The defect-containing substrate has a front surface, a rear surface being opposite to the front surface, and a surface portion adjacent to the front surface. The detect-containing substrate includes a screw dislocation in the surface portion. The front surface of the defect-containing substrate is applied with an external force so that a crystallinity of the surface portion is reduced. After being applied with the external force, the defect-containing substrate is thermally treated so that the crystallinity of the surface portion is recovered.

By the above-described method, the screw distortion in the surface portion of the SiC substrate can be disappeared. Thus, the SiC substrate in which a screw dislocation is restricted in the surface portion can be manufactured.

In a method of manufacturing a SiC substrate according to another aspect of the present invention, a defect-containing substrate made of SiC is prepared. The defect-containing substrate has a front surface, a rear surface being opposite to the front surface, and a surface portion adjacent to the front surface. The defect-containing substrate includes a bulk substrate, a first conductivity type epitaxial layer formed on the bulk substrate, and a second conductivity type epitaxial layer formed on the first conductivity type epitaxial layer. The second conductivity type epitaxial layer has a surface corresponding to the front surface of the defect-containing substrate. The defect-containing substrate includes a screw dislocation in the surface portion. The front surface of the defect-containing substrate is applied with an external force so that a crystallinity of the surface portion is reduced. After being applied with the external force, the defect-containing substrate is thermally treated so that the crystallinity of the surface portion is recovered. In the surface portion, a first conductivity type impurity layer or a second conductivity type impurity layer having an impurity concentration of equal to or more than 1×10²¹ cm⁻³ is formed.

By the above-described manufacturing method, the screw distortion in the surface portion of the defect-containing substrate can be disappeared. Thus, even when the first conductivity type impurity layer or the second conductivity type impurity layer having an impurity concentration of equal to or more than 1×10²¹ cm⁻³ is formed in the surface portion, diffusion of impurities in the defect-containing substrate can be restricted.

### BRIEF DESCRIPTION OF THE DRAWINGS

Additional objects and advantages of the present invention will be more readily apparent from the following detailed description of preferred embodiments when taken together with the accompanying drawings. In the drawings:

FIG. 1A and FIG. 1B are diagrams showing a manufacturing process of a SiC substrate according to a first embodiment of the present invention;

FIG. 2A and FIG. 2B are cross-sectional TEM images of the SiC substrate manufactured by a method according to the first embodiment, and FIG. 2C and FIG. 2D are illustrative views of the cross-sectional TEM images shown in FIG. 2A and FIG. 2B;

FIG. 3A to FIG. 3C are diagrams showing a manufacturing process of a SiC substrate according to a second embodiment of the present invention;

FIG. 4A to FIG. 4D are diagrams showing a manufacturing process of a SiC substrate according to a third embodiment of the present invention;

FIG. 5A to FIG. 5D are diagrams showing a manufacturing process of a SiC substrate according to a fourth embodiment of the present invention;

FIG. 6A to FIG. 6C are diagrams showing a manufacturing process of a SiC substrate according to a fifth embodiment of the present invention; and

FIG. 7A and FIG. 7B are diagrams showing a manufacturing process of a SiC substrate according to a sixth embodiment of the present invention.

### DETAILED DESCRIPTION OF THE PREFERRED EMBODIMENTS

### First Embodiment

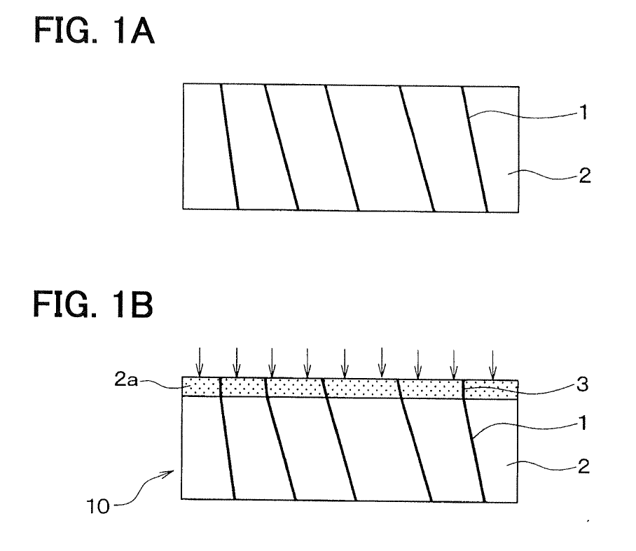

A method of manufacturing a SiC substrate 10 according to a first embodiment of the present invention will be described with reference to FIG. 1A and FIG. 1B.

First, a defect-containing substrate 2 made of SiC is prepared. The defect-containing substrate 2 has a front surface, a rear surface being opposite to the front surface, and a surface portion 2a adjacent to the front surface. The defect-containing substrate 2 includes threading mixed dislocations 1 extending to the front surface. In other words, the defect-containing substrate 2 that includes screw dislocations in the surface portion 2a is prepared.

The defect-containing substrate 2 has an off-angle of from 4 degrees to 8 degrees. The defect-containing substrate 2 is made of 4H—SiC single crystal having a front surface of a (0001) plane. The defect-containing substrate 2 can be prepared, for example, by slicing a SiC single crystal ingot formed by a conventional manufacturing method. In the present embodiment, the threading mixed dislocations 1 include the screw dislocations.

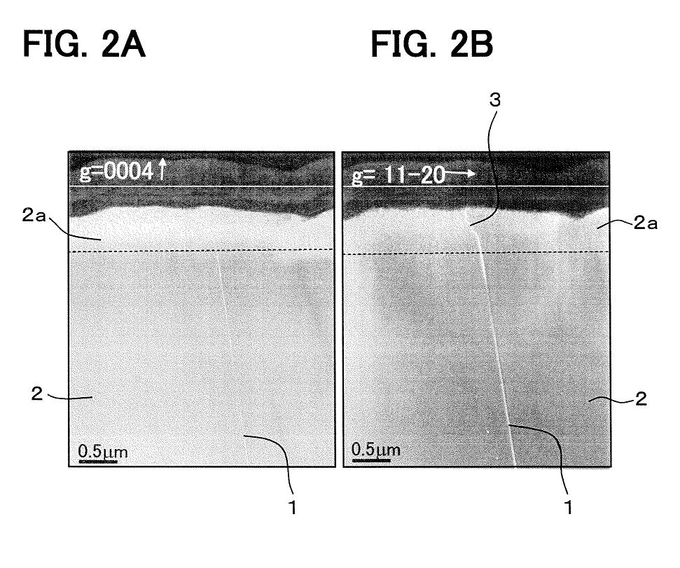

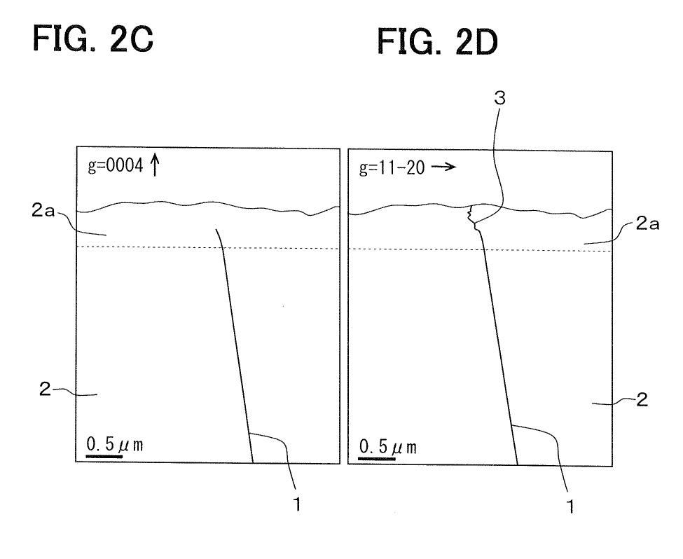

Then, as shown in FIG. 2B, impurity elements are implanted into the defect-containing substrate 2 from the front surface of the (0001) plane. The impurity elements include, for example, N type impurities selected from N, P, As, and Sb, P type impurities selected from B, Al, Ga, and In, or inert impurities selected from Si, C, F, He, Ne, Ar, Kr, and Xe. Accordingly, an external force is applied to the surface portion 2a of the defect-containing substrate 2, distortion is generated in the surface portion 2a, and a crystallinity of the surface portion 2a is reduced. In other words, the surface portion 2a of the defect-containing substrate 2 is changed into amorphous.

When the ion implantation is performed, for example, a temperature of the defect-containing substrate 2 is about 500° C., and an acceleration voltage of the impurity elements is from 20 KeV to 700 KeV. The ion implantation can be performed so that an impurity concentration becomes from 1×10¹⁵ cm⁻³ to 1×10²² cm⁻³. The ion implantation to the front surface of the defect-containing substrate can function as applying an external force the front surface of the defect-containing substrate 2.

Then, the defect-containing substrate 2 is thermally treated so that the crystallinity of the surface portion 2a is recovered. In other words, the surface portion 2a changed into amorphous is recrystallized. The thermal treatment is performed at a temperature that is higher than a temperature at which the defect-containing substrate 2 starts to melt and is less than a temperature at which the defect-containing substrate 2 is sublimed. The thermal treatment is performed at a temperature, for example, from 1400° C. to 1600° C. Accordingly, the SiC substrate 10 according to the present embodiment is formed.

In the surface portion 2a of the SiC substrate 10, screw dislocation components are disappeared from the threading mixed dislocations 1 and edge dislocations 3 are generated.

As described above, in the manufacturing method according to the present embodiment, the crystallinity of the surface portion 2a is reduced by implanting ions from the front surface of the defect-containing substrate 2 and thereby causing distortion in the surface portion 2a. Then, the crystallinity of the surface portion 2a is recovered with the thermal treatment. Accordingly, although a definite reason is not clear, it can be considered that the distortion caused during the ion implantation affects distortion that generates the screw dislocations, and the screw dislocations can be disappeared from the surface portion 2a of the defect-containing substrate 2.

FIG. 2A and FIG. 2B are cross-sectional transmission electron microscope (TEM) images of the SiC substrate 10 manufactured by the method according to the present embodiment. FIG. 2A is an image taken with g=0004, and FIG. 2B is an image taken with g=11-20, where “g” is a diffraction vector. FIG. 2C is an illustrative view of the TEM image shown in FIG. 2A, and FIG. 2D is an illustrative view of the TEM image shown in FIG. 2B.

It is known that a SiC substrate of a hexagonal system may include a screw dislocation having a Burgers vector of α<0001>, an edge dislocation having a Burgers vector of 1/3<2-1-10>, and a mixed dislocation having a Burgers vector of 1/3<2-1-13>. It is also known that when a Burgers vector of a dislocation is “b” and g·b=0, a contrast of the dislocation disappears from a cross-sectional TEM image.

In FIG. 2A, a contrast of the dislocation disappears in the surface portion 2a of the SiC substrate 10. In FIG. 2B, the contrast of the dislocation remains in the surface portion 2a of the SiC substrate 10. Thus, it can be confirmed that the dislocation in the surface portion 2a of the SiC substrate 10 is an edge dislocation 3. In other words, although the defect-containing substrate 2 including the threading mixed dislocations 1 is prepared, when the SiC substrate 10 is manufactured, the crystallinity of the surface portion 2a is reduced by implanting ions and causing distortion, and the crystallinity of the surface portion 2a is recovered by the thermal treatment, and thereby the screw dislocations disappear in the surface portion 2a of the SiC substrate 10 and the threading mixed dislocations 1 in the surface portion 2a are changed into the edge dislocations 3.

The manufacturing method according to the present embodiment can disappear the screw dislocations in the surface portion 2a and can manufacture the SiC substrate 10 in which a screw dislocation is restricted in the surface portion 2a.

Thus, in a case where the SiC substrate 10 is used as a seed crystal and a SiC single crystal is grown on the front surface of the seed crystal, generation of a screw dislocation in the grown SiC single crystal can be restricted because a screw dislocation is restricted in the surface portion 2a, that is, a screw dislocation is restricted on the front surface of the SiC substrate 10 compared with a conventional seed crystal.

In a case where the SiC substrate 10 is used as a substrate of a device, and for example, an epitaxial layer is formed on the front surface of the SiC substrate 10, generation of a screw dislocation in the epitaxial layer can be restricted.

In the manufacturing method according to the present embodiment, only the ion implantation process and the thermal treatment process are required. Thus, the manufacturing process can be simplified compared with the conventional manufacturing method in which a SiC substrate is manufactured while changing a growth direction of a SiC single crystal.

Although the edge dislocations 3 exist in the surface portion 2a of the SiC substrate 10, in a case where the epitaxial layer is formed on the front surface of the SiC substrate 10, the edge dislocations 3 grow in the epitaxial layer, and a screw dislocation is not generated due to the edge dislocations 3.

In the process shown in FIG. 1B, when the ion implantation is performed so that the impurity concentration is equal to or more than 1×10²¹ cm⁻³, the impurities diffuse along the screw dislocations in the threading mixed dislocations 1. However, there is no problem in a case where the SiC substrate 10 manufactured by the method according to the present embodiment is used as a seed crystal. There is also no problem in a case where an epitaxial layer is formed on the front surface of the SiC substrate 10 because layers including a source layer are formed in the epitaxial layer.

### Second Embodiment

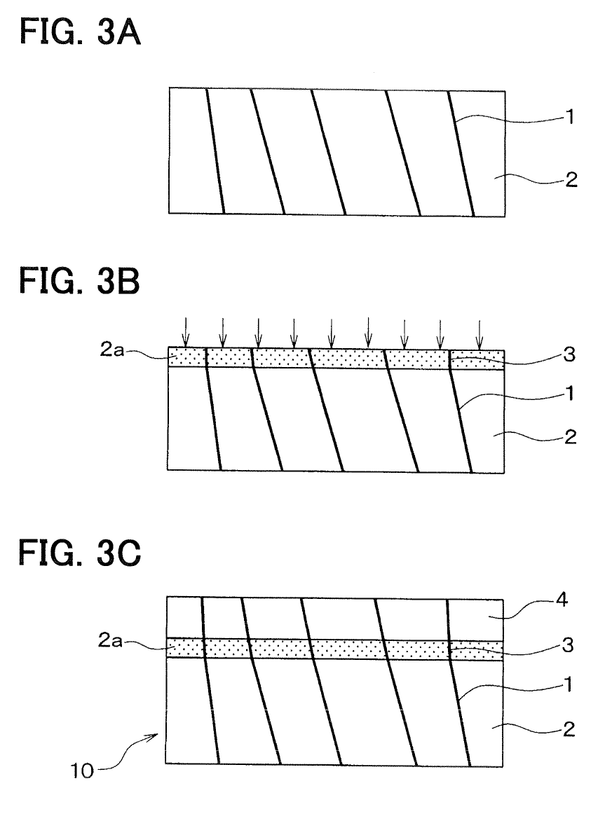

A method of manufacturing a SiC substrate 10 according to a second embodiment of the present invention will be described with reference to FIG. 3A to FIG. 3C. In the method according to the present embodiment, a SiC single crystal is grown after the process shown in FIG. 1B in the first embodiment, and other process is similar to the first embodiment.

During a process shown in FIG. 3A and FIG. 3B, a process similar to the process shown in FIG. 1A and FIG. 1B is performed. Then, as shown in FIG. 3C, a SiC single crystal 4 is formed on the front surface of the defect-containing substrate 2, for example, by a chemical vapor deposition (CVD) method, a sublimation growth method, a liquid growth method, or a gas growth method. Accordingly, the SiC substrate 10 is manufactured.

In the method according to the present embodiment, the SiC single crystal 4 can reduce influence of the distortion of the front surface of the defect-containing substrate 2. Thus, effects similar to the effects of the first embodiment can be achieved and the SiC substrate 10 in which the distortion on the front surface is reduced can be manufactured. Because the SiC single crystal 4 can reduce influence of the distortion of the front surface of the defect-containing substrate 2, in a case where the SiC substrate 10 is used as a seed crystal, a SiC single crystal having a high quality can be grown compared with the first embodiment.

After the process shown in FIG. 3B, in the surface portion 2a of the defect-containing substrate 2, because the screw distortions disappear from the threading mixed dislocations 1, the edge dislocations 3 are generated.

### Third Embodiment

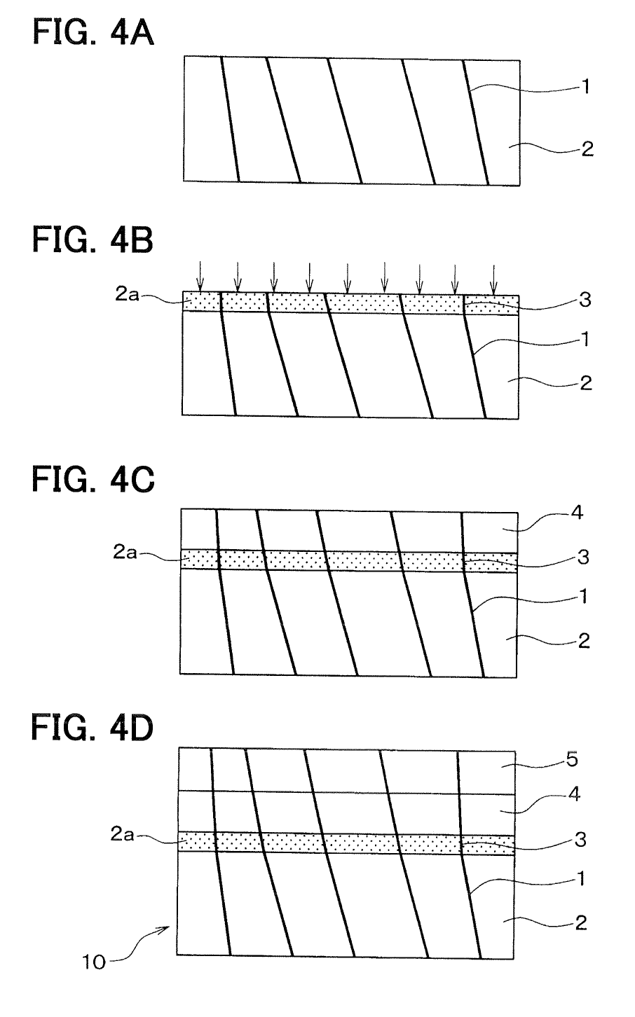

A method of manufacturing a SiC substrate 10 according to a third embodiment of the present invention will be described with reference to FIG. 4A to FIG. 4D. In the method according to the present embodiment, a SiC single crystal is further grown after the process shown in FIG. 3C in the second embodiment, and other process is similar to the second embodiment.

During a process shown in FIG. 4A to FIG. 4C, a process similar to the process shown in FIG. 3A to FIG. 3C is performed. During the process shown in FIG. 4C, the SiC single crystal 4 is epitaxially grown by a CVD method. Then, as shown in FIG. 4D, a SiC single crystal 5 is formed on the SiC single crystal 4 by a sublimation growth method, a liquid growth method, or a gas growth method. Accordingly, the SiC substrate 10 is manufactured.

In the method according to the present method, influence of the distortion on the front surface of the defect-containing substrate 2 can be reduced by the SiC single crystal 4. In addition, influence of distortion of the SiC single crystal 4 can be reduced by the SiC single crystal 5. Thus, effects similar to the effects of the first embodiment can be achieved and the distortion on the front surface of the SiC substrate 10 can be further reduced.

Because the distortion of the front surface of the SiC substrate 10 is further reduced compared with the second embodiment, in a case where the SiC substrate 10 is used as a seed crystal, a SiC single crystal having a higher quality can be grown.

In the present method, the SiC single crystal 4 is epitaxially grown. Thus, the crystallinity of the SiC single crystal 4 can be improved compared with a case where the SiC single crystal 4 is grown by other method such as a sublimation growth method, and the SiC single crystal 4 can be grown with inheriting the defects (distortion) that exist on the front surface of the defect-containing substrate 2. Because the edge dislocations 3 exist on the front surface of the defect-containing substrate 2, the SiC single crystal 4 can be grown with generating the edge dislocations 3. In other words, generation of a screw dislocation due to the edge dislocations 3 that exist on the front surface of the defect-containing substrate 2 can be restricted.

### Fourth Embodiment

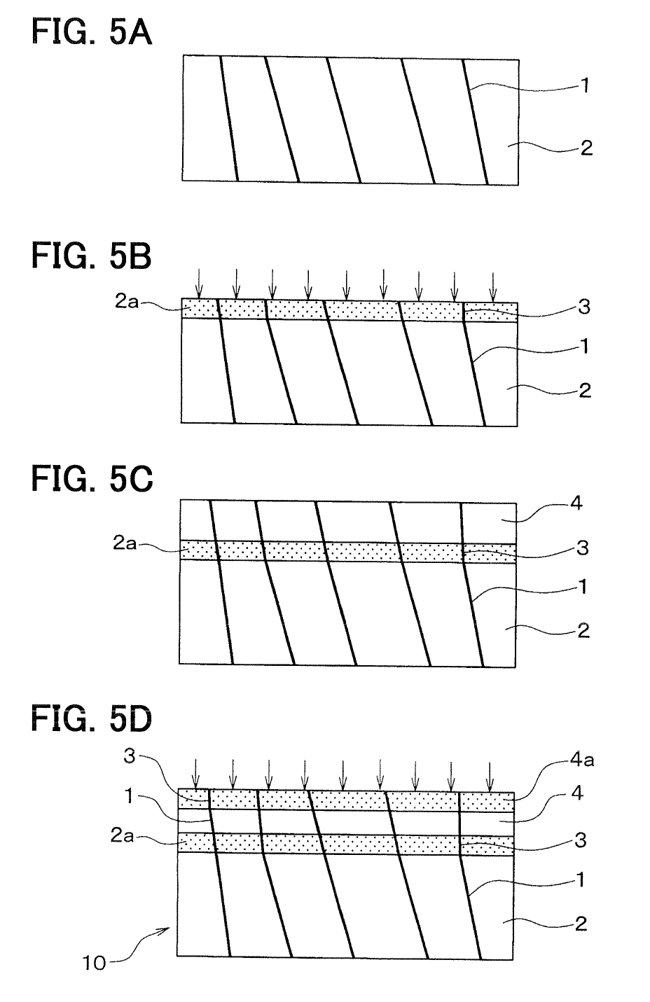

A method of manufacturing a SiC substrate 10 according to a fourth embodiment of the present invention will be described with reference to FIG. 5A to FIG. 5C. In the method according to the present embodiment, an ion implantation and a thermal treatment are further performed after the process shown in FIG. 3C in the second embodiment, and other process is similar to the second embodiment.

During a process shown in FIG. 5A to FIG. 5C, a process similar to the process shown in FIG. 3A to FIG. 3C is performed. Then, as shown in FIG. 5D, impurity elements are implanted from the front surface side of the SiC single crystal 4, that is, an opposite side of SiC single crystal 4 from the front surface of the defect-containing substrate 2. Accordingly, distortion is generated in a surface portion 4a of the SiC single crystal 4, and a crystallinity of the surface portion 4a is reduced. The ion implantation from the front surface side of the SiC single crystal 4 can function as applying an external force the front surface of the SiC single crystal 4. Then, the crystallinity of the surface portion 4a is recovered by a thermal treatment. The ion implantation and the thermal treatment performed in the process shown in FIG. 5D may be performed in a manner similar to the ion implantation and the thermal treatment performed in the process shown in FIG. 1B.

In the manufacturing method according to the present embodiment, even when a part of a screw dislocation component remains in the surface portion 2a in the process shown in FIG. 5B, and a screw dislocation is generated in the SiC single crystal 4 due to the screw dislocation remaining in the surface portion 2a in the process shown in FIG. 5C, because the crystallinity of the surface portion 4a is reduced by implanting ions to the surface portion 4a of the SiC single crystal 4 and causing the distortion in the surface portion 4a and the crystallinity of the surface portion 4a is recovered by the thermal treatment, a screw dislocation generated in the SiC single crystal 4 can be disappeared. Thus, effects similar to the effects of the second embodiment can be achieved, and the SiC substrate 10 in which a screw dislocation in the surface portion 4a is further restricted compared with the second embodiment can be manufactured. Because the screw dislocation in the surface portion 4a is further restricted compared with the second embodiment, in a case where the SiC substrate 10 is used as a seed crystal, a SiC single crystal having a higher quality can be grown.

### Fifth Embodiment

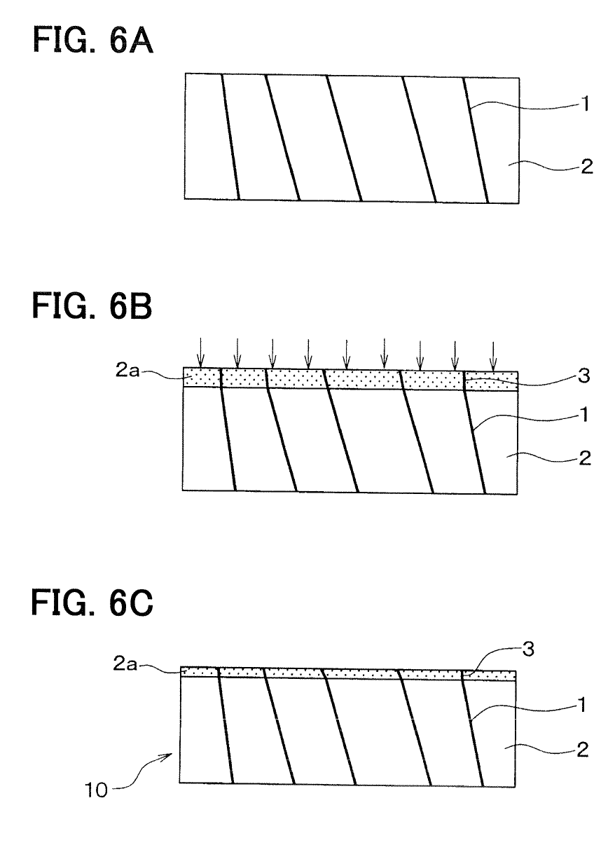

A method of manufacturing a SiC substrate 10 according to a fifth embodiment of the present invention will be described with reference to FIG. 6A to FIG. 6C. In the method according to the present embodiment, a mechanical polishing is performed after the process shown in FIG. 1B in the first embodiment, and other process is similar to the first embodiment.

During a process shown in FIG. 6A and FIG. 6B, a process similar to the process shown in FIG. 1A and FIG. 1B is performed. Then, as shown in FIG. 6C, the front surface of the defect-containing substrate 2 is planarized by chemical mechanical polishing (CMP). Accordingly, the SiC substrate 10 is manufactured.

In the method according to the present embodiment, effects similar to the effects of the first embodiment can be achieved and the SiC substrate 10 having a planarized surface can be manufactured. Thus, in a case where the SiC substrate 10 is used as a seed crystal and a SiC single crystal is grown on the front surface of the SiC substrate 10, generation of distortion and a defect in a grown SiC single crystal due to unevenness of front surface of the SiC substrate 10 can be restricted compared with the first embodiment.

In a case where the SiC substrate 10 is used as a substrate of a device, and for example, an epitaxial layer is formed on the front surface of the SiC substrate 10, generation of distortion and a defect in the epitaxial layer due to unevenness of front surface of the SiC substrate 10 can be restricted compared with the first embodiment.

### Sixth Embodiment

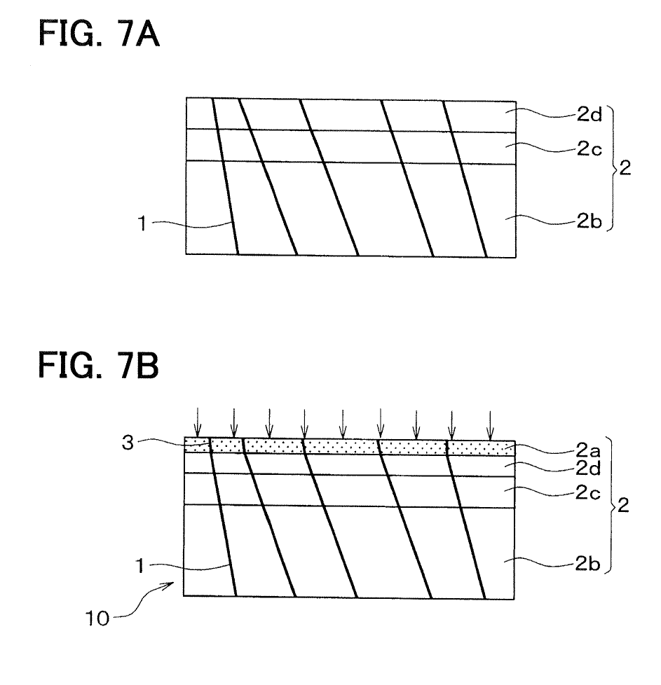

A method of manufacturing a SiC substrate 10 according to a sixth embodiment of the present invention will be described with reference to FIG. 7A and FIG. 7B. In the method according to the present embodiment, a defect-containing substrate 2 different from the detect-containing substrate 2 in the first embodiment is prepared, and other process is similar to the first embodiment.

In the present embodiment, as shown in FIG. 7A, a bulk SiC substrate 2b including threading mixed dislocations 1 is prepared. On a front surface of the bulk SiC substrate 2b, an N type epitaxial layer 2c is formed. On the N type epitaxial layer 2c, a P type epitaxial layer 2d is formed. Accordingly, the defect-containing substrate 2 according to the present embodiment is formed. Because the bulk SiC substrate 2b includes the threading mixed dislocations 1, the N type epitaxial layer 2c and the P type epitaxial layer 2d also include the threading mixed dislocations 1 by inheriting the threading mixed dislocations 1 that exist on the front surface of the bulk SiC substrate 2b. In the present embodiment, the N type epitaxial layer 2c can function as a first conductivity type epitaxial layer, and the P type epitaxial layer 2d can function as a second conductivity type epitaxial layer.

Next, as shown in FIG. 7B, a crystallinity of a surface portion 2a of the P type epitaxial layer 2d is reduced, for example, by implanting Al ions and causing distortion. Then, the defect-containing substrate 2 is thermally treated so that the crystallinity of the surface portion 2a is recovered. Accordingly, the SiC substrate 10 is manufactured.

The implantation of Al ions can be performed so that an impurity concentration becomes from 1×10¹⁵ cm⁻³ to 1×10²⁰ cm⁻³. When the ion implantation is performed so that the impurity concentration becomes equal to or more than 1×10²¹ cm⁻³, the impurities may diffuse along a screw dislocation while implanting ions.

In the method according to the present embodiment, effects similar to the effects of the first embodiment can be achieved, and the SiC substrate 10 in which a screw dislocation is disappeared from the surface portion 2a can be manufactured.

The SiC substrate 10 can be used for manufacturing a SiC semiconductor device such as a MOSFET. In the present case, a source region and a source electrode may be formed, and a contact layer, for example, having an impurity concentration of equal to or more than 1×10²¹ cm⁻³ may be formed in the surface portion 2a with P type impurities. The contact layer can function as an impurity layer.

In a SiC substrate manufactured by the conventional method, a screw dislocation may exist in a surface portion of the SiC substrate. Thus, when a contact layer having an impurity concentration of equal to or more than 1×10²¹ cm⁻³ is formed in the surface portion with P type impurities, the P type impurities may diffuse in the SiC substrate along the screw dislocations, and the defused P type impurities may cause a leak current. However, by the method according to the present embodiment, the SiC substrate 10 in which screw dislocations are disappeared from the surface portion 2a of the P type epitaxial layer 2d can be manufactured. Thus, in a case where the contact layer is formed in the surface portion 2a, the P type impurities do not diffuse in the SiC substrate 10, and generation of leak current can be restricted. A depth of the ion implantation for forming the contact layer needs to be shallower than a depth of the ion implantation for disappearing the screw dislocations.

P type impurities diffuse along screw dislocations when a contact layer having an impurity concentration of 1×10²¹ cm⁻³ is formed in a SiC substrate. Thus, the SiC substrate 10 manufactured by the method according to the present embodiment can be suitably used for manufacturing a SiC semiconductor device that includes a contact layer having an impurity concentration of equal to or more than 1×10²¹ cm⁻³.

### Other Embodiments

Although the present invention has been fully described in connection with the preferred embodiments thereof with reference to the accompanying drawings, it is to be noted that various changes and modifications will become apparent to those skilled in the art.

In the methods according to the above-described embodiments, the external force is applied to the front surface of the defect-containing substrate 2 by implanting ions as an example. The external force may also be applied to the front surface side of the defect-containing substrate 2 by mechanical polishing such as CMP. Accordingly, distortion can be caused in the surface portion 2a of the defect-containing substrate 2 and the crystallinity of the surface portion 2a can be reduced. In the fourth embodiment, the external force is applied to the surface portion 4a of the SiC single crystal 4 by implanting ions as an example. The external force may also be applied to the surface portion 4a of the SiC single crystal 4 by mechanical polishing such as CMP. Accordingly, distortion can be caused in the surface portion 4a of the SiC single crystal 4 and the crystallinity of the surface portion 4a can be reduced.

In the above-described embodiments, the defect-containing substrate 2 made of 4H—SiC single crystal and having a front surface of the (0001) plane is used as an example. The defect-containing substrate 2 may also have a front surface of a (11-20) plane. The defect-containing substrate 2 may also be made of a 2H—SiC single crystal or a 6H—SiC single crystal.

In the above-described embodiments, the defect-containing substrate 2 including the threading mixed dislocations 1 is used as an example. The manufacturing methods according to the above-described embodiments may also be applied to a defect-containing substrate 2 including threading screw dislocations or a defect-containing substrate 2 including screw dislocations only in a surface portion 2a.

In the fifth embodiment, after the process shown in FIG. 5D is performed, another SiC single crystal may also be grown on the SiC single crystal 4 so as to form the SiC substrate 10 in a manner similar to the third embodiment. In the present case, the SiC substrate 10 in which the distortion of the SiC single crystal 4 can be reduced by the SiC single crystal grown on the SiC single crystal 4 can be manufactured.

In the fifth embodiment, the first conductivity type epitaxial layer is the N type epitaxial layer and the second conductivity type epitaxial layer is the P type epitaxial layer as an example. Alternatively, the first conductivity type epitaxial layer may be a P type epitaxial layer and the second conductivity type epitaxial layer may be an N type epitaxial layer. The contact layer may also be formed with N type impurities.

In the fifth embodiment, the distortion is caused in the surface portion 2a by implanting Al ions. The impurities to be implanted may be the P type impurities, the N type impurities, or the inert impurities. In a case where P type impurities or the N type impurities are implanted, the ion implantation may be performed so that the impurity concentration becomes from 1×10¹⁵ cm⁻³ to 1×10²⁰ cm⁻³ so as to restrict diffusion of the impurities along screw dislocations. In a case where the inert impurities are implanted, there is no problem even when the impurities diffuse. Thus, the ion implantation can be performed with a condition similar to the first embodiment.

What is claimed is:

1. A method of manufacturing a silicon carbide substrate, comprising:
preparing a defect-containing substrate made of silicon carbide, the defect-containing substrate having a front surface, a rear surface being opposite to the front surface, and a surface portion adjacent to the front surface, the detect-containing substrate including a screw dislocation in the surface portion;
applying an external force to the front surface of the defect-containing substrate so as to reduce a crystallinity of the surface portion; and
thermally treating the defect-containing substrate after the applying the external force so as to recover the crystallinity of the surface portion.

2. The method according to claim 1, further comprising
growing a silicon carbide single crystal on the front surface of the defect-containing substrate after the thermally treating the defect-containing substrate.

3. The method according to claim 2, further comprising
growing another silicon carbide single crystal on the silicon carbide single crystal, wherein
the growing the silicon carbide single crystal includes epitaxially growing the silicon carbide single crystal by a chemical vapor deposition method, and
the growing the another silicon carbide single crystal includes growing the another silicon carbide single crystal by one of a sublimation growth method, a gas growth method, and a liquid growth method.

4. The method according to claim 2, further comprising:
applying an external force to a front surface of the SiC single crystal so as to reduce a crystallinity of a surface portion of the SiC single crystal; and
thermally treating the SiC single crystal so as to recover the crystallinity of the surface portion of the SiC single crystal.

5. The method according to claim 1, further comprising
mechanically polishing the front surface of the defect-containing substrate after the thermally treating the defect-containing substrate.

6. The method according to claim 1, wherein
the applying the external force to the front surface of the defect-containing substrate includes implanting ions.

7. The method according to claim 6, wherein
the implanting ions includes implanting impurities selected from N, P, As, Sb, B, Al, Ga, In, Si, C, F, He, Ne, Ar, Kr, and Xe.

8. The method according to claim 1, wherein
the thermally treating the defect-containing substrate includes heating the defect-containing substrate at a temperature from 1400° C. to 1600° C.

9. A method of manufacturing a silicon carbide semiconductor, comprising:
preparing a defect-containing substrate made of silicon carbide, the defect-containing substrate having a front surface, a rear surface being opposite to the front surface, and a surface portion adjacent to the front surface, the defect-containing substrate including a bulk substrate, a first conductivity type epitaxial layer formed on the bulk substrate, and a second conductivity type epitaxial layer formed on the first conductivity type epitaxial layer, the second conductivity type epitaxial layer having a surface corresponding to the front surface of the defect-containing substrate, the defect-containing substrate including a screw dislocation in the surface portion;
applying an external force to the front surface of the defect-containing substrate so as to reduce a crystallinity of the surface portion;
thermally treating the defect-containing substrate after the applying the external force so as to recover the crystallinity of the surface portion; and
forming a first conductivity type impurity layer or a second conductivity type impurity layer having an impurity concentration of equal to or more than 1×10²¹ cm⁻³ in the surface portion.

10. The method according to claim 9, wherein
the applying the external force to the front surface of the defect-containing substrate includes implanting ions.

11. The method according to claim 10, wherein
the implanting ions includes implanting impurities selected from N, P, As, Sb, B, Al, Ga, In, Si, C, F, He, Ne, Ar, Kr, and Xe.

12. The method according to claim 9, wherein
the thermally treating the defect-containing substrate includes heating the defect-containing substrate at a temperature from 1400° C. to 1600° C.
